(19) United States
(12) Patent Application Publication
(10) Pub. No.: US 2026/0231815 A1
(43) Pub. Date: Aug. 6, 2026

(54) DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jiaming Shen, Beijing (CN); Haotian Yang, Beijing (CN); Baofu Lu, Beijing (CN); Xiaodong Hao, Beijing (CN); Xiaoliang Fu, Beijing (CN); Kang Wang, Beijing (CN); Jiatong Jiang, Beijing (CN); Chuxiang Wang, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/147,420

(22) PCT Filed: Jun. 12, 2024
(86) PCT No.: PCT/CN2024/098533

§ 371 Date: Jul. 11, 2025

(30) Foreign Application Priority Data
Jul. 25, 2023 (CN) 202310921011.2

(51) Int. Cl. H10W 76/15; H10W 40/22

(52) U.S. Cl. CPC H10W 76/15; H10W 40/22

(57) ABSTRACT

A display module is provided, and it includes a display panel. The display panel includes a display region, a bending region and a binding region in a first direction, and the bending region is bent so that the binding region is located at a backlight side of the display region. In a case that the bending region is in a bending state, a heat dissipation function layer is arranged between the display region and the binding region, and a first rigid support layer is arranged between the heat dissipation function layer and the binding region. A display device is further provided.

### CROSS-REFERENCE TO RELATED APPLICATION

This application claims a priority of the Chinese patent application No. 202310921011.2 filed on Jul. 25, 2023, which is incorporated herein by reference in its entirety.

### TECHNICAL FIELD

The present disclosure relates to the manufacture of a display product, in particular to a display module and a display device.

### BACKGROUND

Along with the rapid development of the display technology, users increasingly tend to use full-screen terminals, so it is required to continuously increase a design capability of a narrow bezel of a module. In addition, more attention is paid to waterproofness of a product.

Taking a mobile phone as an example, a waterproof adhesive is applied between a middle frame of the machine and a display module, and the waterproof adhesive may occupy a space for a lower frame, so finally the product still has a wide bezel. In order to achieve the design of a narrow bezel, as a current scheme, a position of the waterproof adhesive is moved forward, and the waterproof adhesive flows through Panel Tail (binding region) to be in contact with the middle frame. Although a narrow bezel is achieved using this method, the middle frame of the machine is in direct contact with Panel. During a mechanical strength test, e.g., a drop test, an external force applied to the machine is directly transferred to Panel Tail, and such defects as peeling and deformation occurs for the Panel, so a failure occurs for the module.

### SUMMARY

An object of the present disclosure is to provide a display module and a display device, so as to achieve a narrow bezel while ensuring a waterproof function, and improve the strength of the display module.

In one aspect, the present disclosure provides in some embodiments a display module, including a display panel. The display panel includes a display region, a bending region and a binding region in a first direction, and the bending region is bent so that the binding region is located at a backlight side of the display region. In a case that the bending region is in a bending state, a heat dissipation function layer is arranged between the display region and the binding region, and a first rigid support layer is arranged between the heat dissipation function layer and the binding region.

In a possible embodiment of the present disclosure, in a second direction, the first rigid support layer has a first central region and first peripheral regions arranged at two opposite sides of the first central region, and an orthogonal projection of the binding region onto the first rigid support layer is located in the first central region; in the second direction, the heat dissipation function layer has a second central region and second peripheral regions arranged at two opposite sides of the second central region, and an orthogonal projection of the first rigid support layer onto the heat dissipation function layer is located in the second central region; and the second direction is perpendicular to the first direction, and the second direction is perpendicular to a light-exiting direction of the display panel.

In a possible embodiment of the present disclosure, the heat dissipation function layer is provided with a groove at a side facing the first rigid support layer, and a portion of the first rigid support layer is inserted into the groove.

In a possible embodiment of the present disclosure, the heat dissipation function layer includes a metal layer close to the binding region, and in a light-exiting direction of the display panel, a depth of the groove is smaller than a thickness of the metal layer.

In a possible embodiment of the present disclosure, the heat dissipation function layer includes a metal layer close to the binding region, and a foam layer arranged at a side of the metal layer away from the binding region. In a light-exiting direction of the display panel, a depth of the groove is greater than a thickness of the metal layer, and the depth of the groove is smaller than or equal to a sum of the thickness of the metal layer and a thickness of the foam layer.

In a possible embodiment of the present disclosure, the heat dissipation function layer includes a stainless steel heat dissipation plate, and in a light-exiting direction of the display panel, a depth of the groove is smaller than or equal to a thickness of the stainless steel heat dissipation plate.

In a possible embodiment of the present disclosure, in a second direction, a length of the groove is smaller than 0.5 mm, the second direction is perpendicular to the first direction, and the second direction is perpendicular to a light-exiting direction of the display panel.

In a possible embodiment of the present disclosure, the first rigid support layer is a stainless steel support plate.

In a possible embodiment of the present disclosure, a second rigid support layer is arranged at a side of the binding region away from the display region.

In a possible embodiment of the present disclosure, in the second direction, the binding region includes a third central region and third peripheral regions arranged at two opposite sides of the third central region, and an orthogonal projection of the second rigid support layer onto the binding region is located in the third central region.

In a possible embodiment of the present disclosure, in the second direction, the second rigid support layer includes a fourth central region and fourth peripheral regions arranged at two opposite sides of the fourth central region, an orthogonal projection of the binding region onto the second rigid support layer is located in the fourth central region, and an elastic buffer layer is arranged between the fourth peripheral region and the heat dissipation function layer.

In a possible embodiment of the present disclosure, an orthogonal projection of the elastic buffer layer onto the heat dissipation function layer is completely located in the heat dissipation function layer.

In a possible embodiment of the present disclosure, a gap is provided between the elastic buffer layer and the second rigid support layer.

In a possible embodiment of the present disclosure, the first rigid support layer includes a graphite layer made of a graphite material.

In a possible embodiment of the present disclosure, a driving Integrated Circuit (IC) is arranged at a side of the binding region away from the display region, and in the second direction, a gap between the second rigid support layer and the driving IC is 20 μm to 30 μm.

In another aspect, the present disclosure provides in some embodiments a display device, including the above-mentioned display module and a middle frame outside the display module. The display module further includes a cover plate arranged at a light-exiting side of the display panel; a second rigid support layer is arranged at a side of the binding region away from the display region; the cover plate includes a first region not covered by the display panel, the first region includes a first sub-region corresponding to the binding region and a second sub-region other than the first sub-region, and a first adhesive barrier layer is arranged on the second sub-region and coupled to the middle frame. The display device further includes a second adhesive barrier layer, the second adhesive barrier layer and the first adhesive barrier layer form an annular structure, and the second adhesive barrier layer covers the second rigid support layer, a portion of the binding region not covered by the second rigid support layer, a portion of the first rigid support layer not covered by the binding region, a portion of the heat dissipation function layer not covered by the first rigid support layer, and a portion of the cover plate.

### BRIEF DESCRIPTION OF THE DRAWINGS

Fig. I is a schematic view showing a display module in the related art;

FIG. 2 is another schematic view showing the display module in the related art;

FIG. 3 is yet another schematic view showing the display module in the related art;

FIG. 4 is still yet another schematic view showing the display module in the related art;

FIG. 5 is a schematic view showing a display module according to one embodiment of the present disclosure;

FIG. 6 is another schematic view showing the display module according to one embodiment of the present disclosure;

FIG. 7 is yet another schematic view showing the display module according to one embodiment of the present disclosure;

FIG. 8 is still yet another schematic view showing the display module according to one embodiment of the present disclosure;

FIG. 9 is still yet another schematic view showing the display module according to one embodiment of the present disclosure;

FIG. 10 is still yet another schematic view showing the display module according to one embodiment of the present disclosure;

FIG. 11 is still yet another schematic view showing the display module according to one embodiment of the present disclosure;

FIG. 12 is still yet another schematic view showing the display module according to one embodiment of the present disclosure;

FIG. 13 is still yet another schematic view showing the display module according to one embodiment of the present disclosure; and

FIG. 14 is still yet another schematic view showing the display module according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

FIG. 1 is a schematic view showing a state where a display module is assembled with a middle frame in the related art. During the assembling of a machine, an edge of a cover plate 1 is lapped onto the middle frame 10, and a waterproof adhesive is applied at an inner side of a lapping position to form a waterproof adhesive layer 3. Due to the particularity of this structure, it is impossible to provide a screen of the machine with a narrow lower frame (which is affected by a lapping area of the middle frame and a minimum adhesive application area).

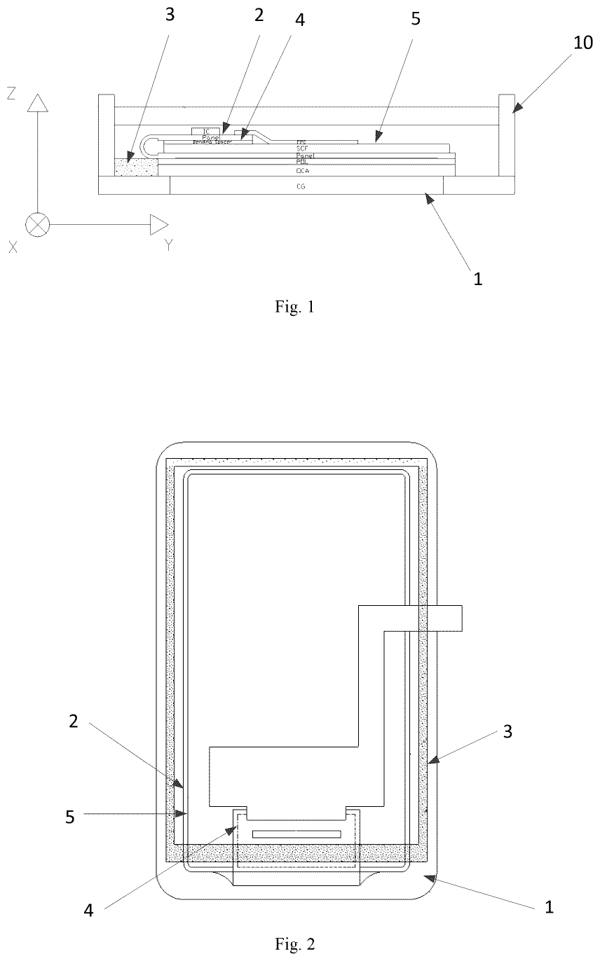

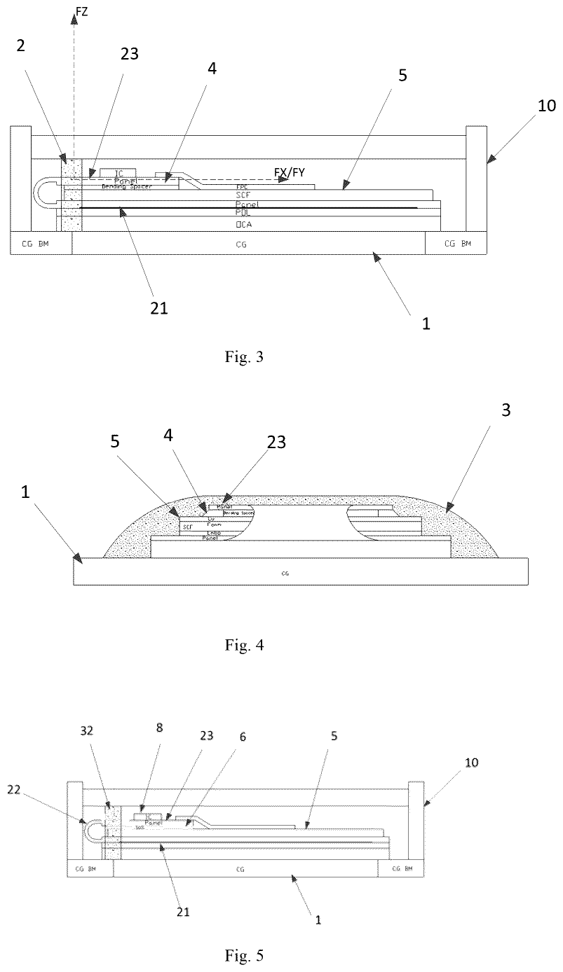

FIG. 2 is a schematic view showing a display module in a narrow-bezel display device in the related art, and FIG. 3 is a schematic view showing a state where the display module is assembled with the middle frame in the narrow-bezel display device in the related art. As compared with the structure in FIG. 1, the waterproof adhesive layer 3 is moved forward (i.e., moved to the right as indicated in the drawings).

A display panel 2 includes a display region, a bending region and a binding region arranged sequentially in a first direction. In a case that the bending region is in a bending state, the binding region is located at a backlight side of the display region. The waterproof adhesive layer 3 is directly applied to a side of the binding region away from the display region, so a portion of the waterproof adhesive layer 3 is in contact with the binding region, and the other portion of the waterproof adhesive layer 3 is in contact with the other members of the machine, e.g., a main board. In this way, it is able to prevent moistures from entering the display module (such elements as IC and FPC are arranged on the right of the waterproof adhesive layer). However, there exist the following defects. The middle frame 10 is directly coupled to the binding region of the display panel via the waterproof adhesive layer 3, so in a case that the machine drops, a force applied to the middle frame 10 in various directions is directly transferred to the display panel via the waterproof adhesive layer 3. FIG. 3 shows a force analysis for the display panel in a case that the machine drops. For ease of understanding, the force is orthogonally decomposed into a positive pressure Fz applied to the display panel and shear forces Fx and Fy in a horizontal plane. As compared with a conventional non-narrow-bezel scheme (a structure with a wide bezel as shown in FIG. 1), the middle frame 10 is coupled to the cover plate 1, so the display panel has larger strength in a case that the machine drops. However, in a narrow-bezel scheme, a force is transferred via the middle frame to the display panel, so a failure may occur for the display panel.

In order to solve the above-mentioned problems, as shown in FIGS. 5 to 14, the present disclosure provides in some embodiments a display module, which includes a display panel. The display panel includes a display region 21, a bending region 22 and a binding region 23 in a first direction (direction Y in FIG. 1), and the bending region 22 is bent so that the binding region 23 is located at a backlight side of the display region 21. In a case that the bending region 22 is in a bending state, a heat dissipation function layer 5 is arranged between the display region 21 and the binding region 23, and a first rigid support layer 6 is arranged between the heat dissipation function layer 5 and the binding region 23.

In the related art, an elastic support layer 4 is arranged between the heat dissipation function layer 5 and the binding region 23 as shown in Figs. I to 4, so as to ensure a bending radius of the bending region 22. However, the elastic support layer includes a polyethylene terephthalate (PET) base material layer and adhesive layer arranged at two opposite sides of the PET base material layer. In a case that a positive pressure is applied to the binding region 23 of the display panel (in a light-exiting direction of the display panel), the elastic support layer may deform, so a line on the binding region 23 of the display panel may crack. In the embodiments of the present disclosure, the elastic support layer is replaced with the first rigid support layer 6, and in a case that a positive pressure is applied to the binding region 23 of the display panel, it does not deform, so it is able to improve the strength of the binding region 23 of the display panel, and transfer the force applied to the binding region 23 to the heat dissipation function layer 5, i.e., the pressure is not withstood by the binding region 23 itself. In this way, it is able to prevent the line at each film layer in the binding region 23 from cracking, thereby to improve the strength of the entire display panel, and reduce the risk of failure.

It should be appreciated that, in the embodiments of the present disclosure, in a case that the elastic support layer is replaced with the first rigid support layer 6, an overall thickness of the display device is not increased.

In the related art, the elastic support layer is arranged between the heat dissipation function layer 5 and the binding region 23, so as to ensure a bending radius of the bending region 22. However, the elastic support layer includes a PET base material layer and adhesive layer arranged at two opposite sides of the PET base material layer. The PET base material layer and the adhesive layers are formed integrally, and a side surface of the adhesive layer is flush with a side surface of the PET base material layer. After the assembling of the binding region 23 of the display panel, an orthogonal projection of the elastic support layer onto the binding region 23 needs to be located in the binding region 23, i.e., the elastic support layer needs to be indented relative to an outer contour of the binding region 23, as shown in FIG. 4. During the formation of the waterproof adhesive layer, there is a height difference between a position where an adhesive is applied and the binding region 23, bubbles easily occur. The bubbles are generated naturally and inevitable in the process, but they may expand in a reliability test, and a waterproof region is broken, resulting in a failure in the waterproofness. In order to solve this problem, in the embodiments of the present disclosure, in a second direction (direction X in FIG. 1, which is perpendicular to the first direction and perpendicular to a light-exiting direction of the display panel), the first rigid support layer 6 is expanded, so that an edge of the binding region 23, an edge of the first rigid support layer 6, an edge of the heat dissipation function layer and an edge of the cover plate 1 at a same side form a step-like structure. At this time, a waterproof adhesive may be leveled onto a target surface in a better manner, so as to prevent the occurrence of bubbles due to picking, attach the waterproof adhesive onto a side surface of the display module in a better manner, and prevent moistures from entering the display module. In addition, it is able to provide an excellent attachment effect, prevent the occurrence of bubbles in the waterproof adhesive due to picking, and improve the assembling reliability of the entire display device.

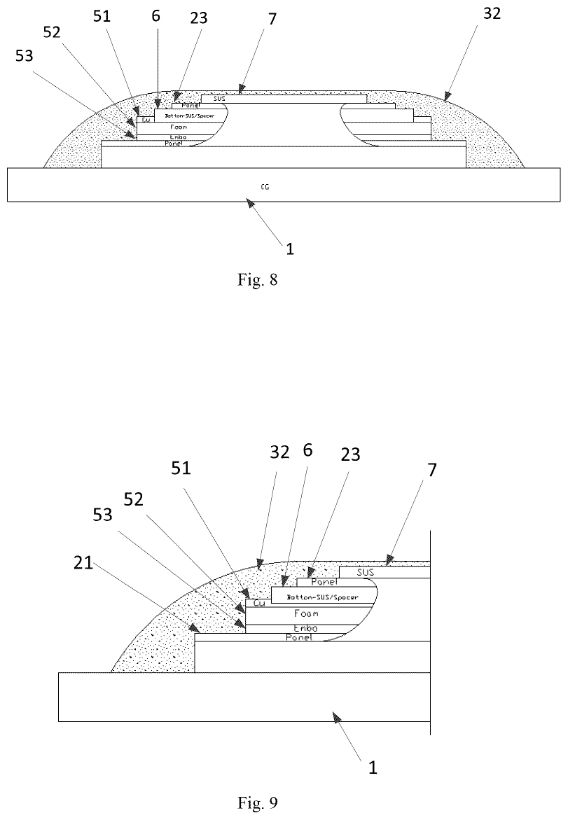

To be specific, as shown in FIG. 8, in the second direction, the first rigid support layer 6 has a first central region and first peripheral regions arranged at two opposite sides of the first central region, and an orthogonal projection of the binding region 23 onto the first rigid support layer 6 is located in the first central region; in the second direction, the heat dissipation function layer 5 has a second central region and second peripheral regions arranged at two opposite sides of the second central region, and an orthogonal projection of the first rigid support layer onto the heat dissipation function layer 5 is located in the second central region; and the second direction is perpendicular to the first direction, and the second direction is perpendicular to a light-exiting direction of the display panel.

It should be appreciated that, the first rigid support layer 6 is a rigid support structure, the first rigid support layer 6 is coupled to the binding region 23 via an adhesive layer, and the adhesive layer is formed through applying an adhesive or attaching an adhesive tape. The first rigid support layer 6 and the adhesive layer are separate structures, so a size of the adhesive layer may be set according to the practical need (i.e., a size of the adhesive layer may be different from a size of the first rigid support layer 6). In a case that the first rigid support layer 6 is expanded relative to the binding region 23, the size of the adhesive layer may be set according to a size of the binding region 23, i.e., the adhesive layer may be indented, so as to prevent the expansion of the first rigid support layer 6 from being adversely affected while ensuring that the first rigid support layer 6 is coupled to the binding region 23.

As shown in FIGS. 9 to 14, for example, the heat dissipation function layer 5 is provided with a groove at a side facing the first rigid support layer 6, and a portion of the first rigid support layer 6 is inserted into the groove.

Through the groove, it is able to receive and fix the first rigid support layer 6. In a case that the machine drops, the force applied to the machine is transferred to the first rigid support layer 6 via the waterproof adhesive layer, the pressure applied in a direction Z is transferred downward to the heat dissipation function layer 5 via the first rigid support layer 6, and the shear force is transferred to the groove of the heat dissipation function layer 5 via the first rigid support layer 6. Due to a limiting effect of the groove, a majority of the force in a shearing direction is absorbed, so as to ensure the strength of the binding region 23.

A depth of the groove may be set according to the practical need, and several structural forms will be described hereinafter.

As shown in FIG. 9, for example, the heat dissipation function layer 5 includes a metal layer 51 close to the binding region 23, and in a light-exiting direction of the display panel, a depth of the groove is smaller than a thickness of the metal layer 51.

During the implementation, in the light-exiting direction of the display panel, the depth of the groove is, but not limited to, a half of the thickness of the metal layer 51.

For example, in the light-exiting direction of the display panel, the depth of the groove is 0.015 mm to 0.30 mm.

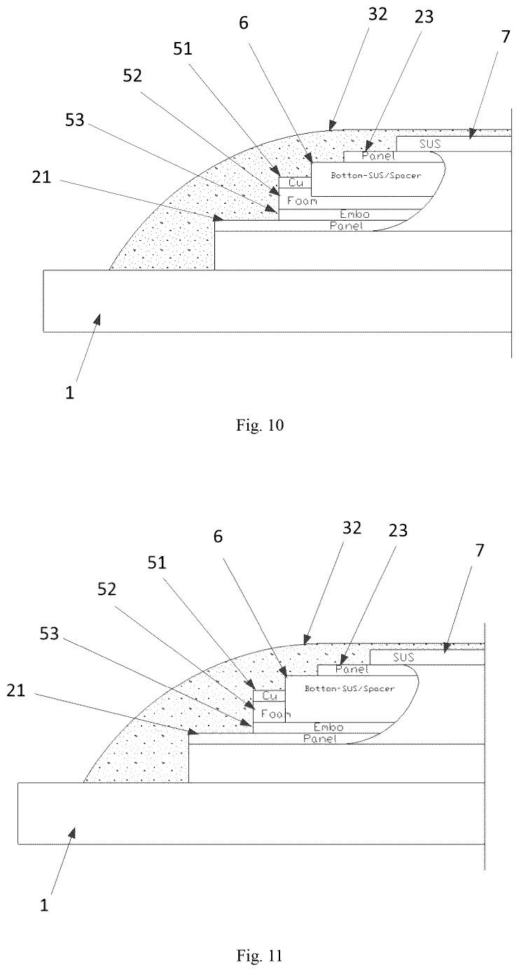

For example, the heat dissipation function layer 5 includes a metal layer 51 close to the binding region 23, and a foam layer 52 arranged at a side of the metal layer 51 away from the binding region 23. In a light-exiting direction of the display panel, a depth of the groove is greater than a thickness of the metal layer 51, and the depth of the groove is smaller than or equal to a sum of the thickness of the metal layer 51 and a thickness of the foam layer 52. In FIG. 10, in the light-exiting direction of the display panel, the depth of the groove is greater than the thickness of the metal layer 51, and smaller than the sum of the thickness of the metal layer 51 and the thickness of the foam layer 52. In FIG. 11, in the light-exiting direction of the display panel, the depth of the groove is greater than the thickness of the metal layer 51, and equal to the sum of the thickness of the metal layer 51 and the thickness of the foam layer 52.

For example, the heat dissipation function layer 5 further includes a grid-like adhesive layer 53 arranged at a side of the foam layer 52 away from the metal layer 51, and in a case that the depth of the groove is equal to the sum of the thickness of the metal layer 51 and the thickness of the foam layer 52, i.e., in a case that the groove penetrates through the metal layer 51 and the foam layer 52, the first rigid support layer 6 is directly in contact with the grid-like adhesive layer 53.

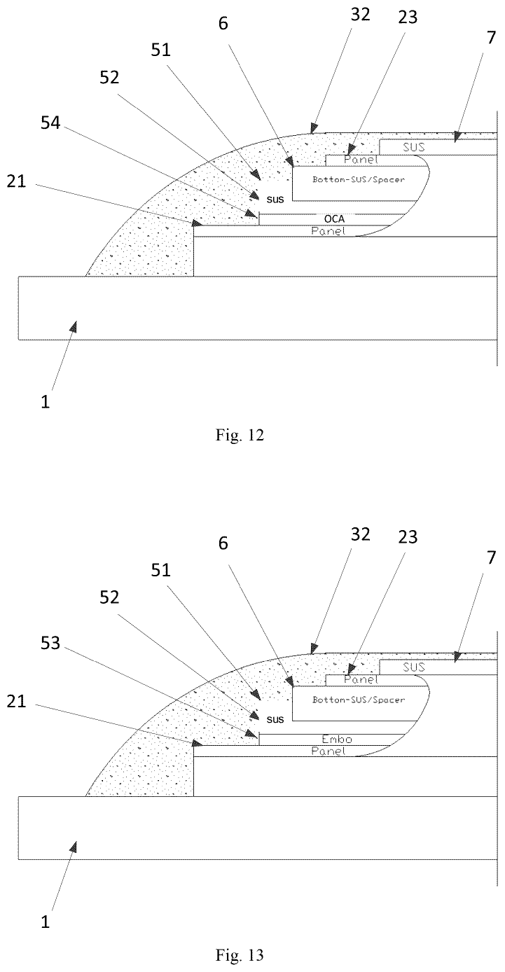

As shown in FIGS. 12 and 13, for example, the heat dissipation function layer 5 includes a stainless steel heat dissipation plate, the stainless steel heat dissipation plate is coupled to the display region 21 of the display panel via an optical clear adhesive layer 54 or the grid-like adhesive layer 53, and the depth of the groove is smaller than or equal to a thickness of the stainless steel heat dissipation plate in the light-exiting direction of the display panel.

For example, in the second direction, a length of the groove is smaller than 0.5 mm, the second direction is perpendicular to the first direction, and the second direction is perpendicular to the light-exiting direction of the display panel.

In some embodiments of the present disclosure, in the second direction, a width of the groove is, but not limited to, 0.1 mm to 0.2 mm.

For example, the first rigid support layer 6 is a stainless steel support plate.

The stainless steel support plate may provide a support effect, increase the strength of the binding region 23, and prevent the occurrence of a failure for the display panel due to the deformation of the binding region 23 in a case of an external force. In addition, through the stainless steel support plate, it is able to improve the heat dissipation effect.

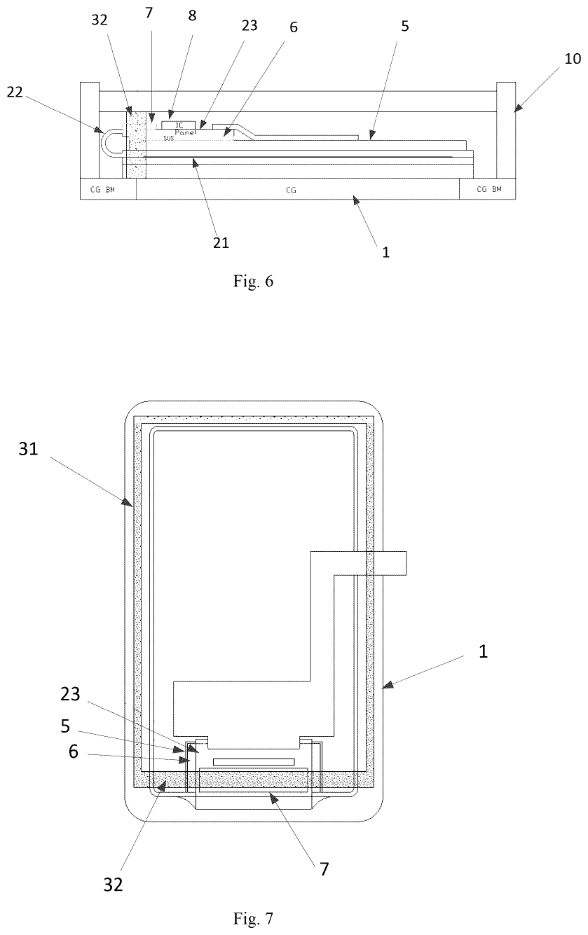

As shown in FIGS. 6 to 14, for example, a second rigid support layer 7 is arranged at a side of the binding region 23 away from the display region 21.

Through the cooperation of the first rigid support layer 6 and the second rigid support layer 7, it is able to ensure the strength of upper and lower surfaces of the binding region 23. In a case that an external force is applied, a vertical force (positive pressure) applied to the binding region 23 is directly transferred to the heat dissipation function layer 5 under the binding region 23, i.e., the vertical force is not withstood by the binding region 23 itself. In this way, it is able to prevent the line at each film layer in the binding region 23 from cracking, improve the strength of the entire binding region 23, and reduce the risk of a failure.

For example, in the second direction, the binding region 23 includes a third central region and third peripheral regions arranged at two opposite sides of the third central region, and an orthogonal projection of the second rigid support layer 7 onto the binding region 23 is located in the third central region.

Based on the above, the second rigid support layer 7 is indented relative to the binding region 23, and in the second direction, an edge of the second rigid support layer 7, an edge of the binding region 23, an edge of the first rigid support layer 6, an edge of the heat dissipation function layer 5 and an edge of the cover plate 1 at a same side form a step-like structure. At this time, the waterproof adhesive may be leveled onto a target surface in a better manner, so as to prevent the occurrence of bubbles due to picking, attach the waterproof adhesive onto a side surface of the display module in a better manner, and prevent moistures from entering the display module.

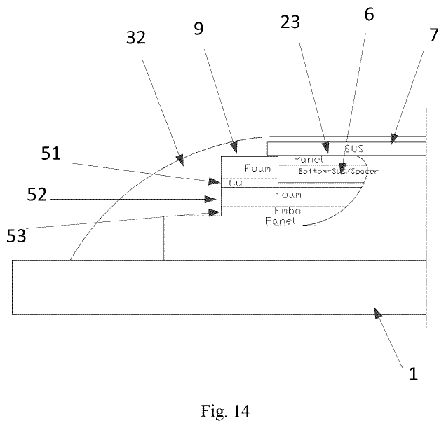

As shown in FIG. 14, for example, in the second direction, the second rigid support layer 7 includes a fourth central region and fourth peripheral regions arranged at two opposite sides of the fourth central region, an orthogonal projection of the binding region 23 onto the second rigid support layer 7 is located in the fourth central region, and an elastic buffer layer 9 is arranged between the fourth peripheral region and the heat dissipation function layer 5.

Based on the above, in a case that a force applied to the machine, after the positive pressure applied to the display module exceeds a predetermined value, the pressure applied to the binding region 23 is transferred to the elastic buffer layer 9. At this time, the elastic buffer layer 9 has a buffering effect, so as to ensure an impression effect at a front side.

For example, the elastic buffer layer 9 may be, but not limited to, foam.

For example, an orthogonal projection of the elastic buffer layer 9 onto the heat dissipation function layer 5 is completely located in the heat dissipation function layer 5.

For example, in the second direction, an edge of the heat dissipation function layer 5 is not covered by the elastic buffer layer 9, so that in the second direction, an edge of the second rigid support layer 7, an edge of the elastic buffer layer 9, an edge of the first rigid support layer 6, an edge of the heat dissipation function layer 5 and an edge of the cover plate 1 at a same side form a step-like structure. At this time, the waterproof adhesive may be leveled onto a target surface in a better manner, so as to prevent the occurrence of bubbles due to picking, attach the waterproof adhesive onto a side surface of the display module in a better manner, and prevent moistures from entering the display module.

For example, a gap is provided between the elastic buffer layer 9 and the second rigid support layer 7.

For example, the gap is 0.01 mm to 0.2 mm, so as to ensure an elastic buffering effect.

For example, a portion of the second rigid support layer 7 not covered by the binding region 23 has a length of 1 mm to 2 mm, so as to prevent any interference on the assembling of the other members.

It should be appreciated that, in a case that the elastic buffer layer 9 is arranged between the second rigid support layer 7 and the heat dissipation function layer 5, the force applied to the binding region 23 is buffered by the elastic buffer layer 9 and transferred to the heat dissipation function layer 5 via the elastic buffer layer 9, so in some embodiments of the present disclosure, the first rigid support layer 6 may be made of any other material for providing a flat surface other than stainless steel. For example, the first rigid support layer 6 includes a graphite layer made of a graphite material.

It should be appreciated that, the first rigid support layer 6 includes a plurality of graphite layers laminated one on another, so as to ensure the support strength and prevent the deformation thereof.

For example, a driving IC 8 is arranged at a side of the binding region 23 away from the display region 21, and in the second direction, a gap between the second rigid support layer 7 and the driving IC 8 is 20 μm to 30 μm.

In a case that the first rigid support layer 6 includes the graphite layer, the graphite layer is in direct contact with the metal layer 51 of the heat dissipation function layer 5, so it is able to rapidly transfer the heat in the vicinity of the driving IC 8 to a surface of the heat dissipation function layer 5, thereby to reduce a local temperature of the binding region 23 in the vicinity of the driving IC 8.

The present disclosure further provides in some embodiments a display device, which includes the above-mentioned display module and a middle frame 10 outside the display module. The display module further includes a cover plate 1 arranged at a light-exiting side of the display panel; a second rigid support layer 7 is arranged at a side of the binding region 23 away from the display region 21; the cover plate 1 includes a first region not covered by the display panel, the first region includes a first sub-region corresponding to the binding region 23 and a second sub-region other than the first sub-region, and a first adhesive barrier layer 31 is arranged on the second sub-region and coupled to the middle frame 10. The display device further includes a second adhesive barrier layer 32, the second adhesive barrier layer 32 and the first adhesive barrier layer 31 form an annular structure, and the second adhesive barrier layer 32 covers the second rigid support layer, a portion of the binding region 32 not covered by the second rigid support layer 7, a portion of the first rigid support layer 6 not covered by the binding region 23, a portion of the heat dissipation function layer 5 not covered by the first rigid support layer 6, and a portion of the cover plate 1.

Through the cooperation of the first rigid support layer 6 and the second rigid support layer 7, it is able to increase the strength of the binding region 23. In a case that an external force is applied, a vertical force (positive pressure) applied to the binding region 23 is directly transferred to the heat dissipation function layer 5 under the binding region 23, i.e., the vertical force is not withstood by the binding region 23 itself. In this way, it is able to prevent the line at each film layer in the binding region 23 from cracking, improve the strength of the entire binding region 23, and reduce the risk of a failure.

In a case that the second adhesive barrier layer 32 and the first adhesive barrier layer 31 form an annular structure, it is able to prevent the moistures from entering the display module.

In a case that the second adhesive barrier layer 32 covers the second rigid support layer, a portion of the binding region 32 not covered by the second rigid support layer 7, a portion of the first rigid support layer 6 not covered by the binding region 23, a portion of the heat dissipation function layer 5 not covered by the first rigid support layer 6, and a portion of the cover plate 1, it is able to provide a narrow bezel.

For example, the first adhesive barrier layer 31 is made of a same material as the second adhesive barrier layer 32, e.g., a waterproof adhesive.

For example, the first adhesive barrier layer 31 is made of a same material as the second adhesive barrier layer 32. The first adhesive barrier layer 31 and the second adhesive barrier layer 32 may be formed through injection molding using glue, a solid adhesive, a Pressure Sensitive Adhesive (PSA), a tape or any material having a support and adhesion effect.

It should be appreciated that, the above embodiments are for illustrative purposes only, and but shall not be construed as limiting the scope of the present disclosure. A person skilled in the art may further make improvements and modifications without departing from the spirit and essence of the present disclosure, and these improvements and modifications shall also fall within the scope of the present disclosure.

1. A display module, comprising a display panel, wherein the display panel comprises a display region, a bending region and a binding region in a first direction, and the bending region is bent so that the binding region is located at a backlight side of the display region, wherein in a case that the bending region is in a bending state, a heat dissipation function layer is arranged between the display region and the binding region, and a first rigid support layer is arranged between the heat dissipation function layer and the binding region.

2. The display module according to claim 1, wherein in a second direction, the first rigid support layer has a first central region and first peripheral regions arranged at two opposite sides of the first central region, and an orthogonal projection of the binding region onto the first rigid support layer is located in the first central region;
in the second direction, the heat dissipation function layer has a second central region and second peripheral regions arranged at two opposite sides of the second central region, and an orthogonal projection of the first rigid support layer onto the heat dissipation function layer is located in the second central region; and
the second direction is perpendicular to the first direction, and the second direction is perpendicular to a light-exiting direction of the display panel.

3. The display module according to claim 1, wherein the heat dissipation function layer is provided with a groove at a side facing the first rigid support layer, and a portion of the first rigid support layer is inserted into the groove.

4. The display module according to claim 3, wherein the heat dissipation function layer comprises a metal layer close to the binding region, and in a light-exiting direction of the display panel, a depth of the groove is smaller than a thickness of the metal layer.

5. The display module according to claim 3, wherein the heat dissipation function layer comprises a metal layer close to the binding region, and a foam layer arranged at a side of the metal layer away from the binding region, wherein in a light-exiting direction of the display panel, a depth of the groove is greater than a thickness of the metal layer, and the depth of the groove is smaller than or equal to a sum of the thickness of the metal layer and a thickness of the foam layer.

6. The display module according to claim 3, wherein the heat dissipation function layer comprises a stainless steel heat dissipation plate, and in a light-exiting direction of the display panel, a depth of the groove is smaller than or equal to a thickness of the stainless steel heat dissipation plate.

7. The display module according to claim 3, wherein in a second direction, a length of the groove is smaller than 0.5 mm, the second direction is perpendicular to the first direction, and the second direction is perpendicular to a light-exiting direction of the display panel.

8. The display module according to claim 1, wherein the first rigid support layer is a stainless steel support plate.

9. The display module according to claim 2, wherein a second rigid support layer is arranged at a side of the binding region away from the display region.

10. The display module according to claim 9, wherein in the second direction, the binding region comprises a third central region and third peripheral regions arranged at two opposite sides of the third central region, and an orthogonal projection of the second rigid support layer onto the binding region is located in the third central region.

11. The display module according to claim 9, wherein in the second direction, the second rigid support layer comprises a fourth central region and fourth peripheral regions arranged at two opposite sides of the fourth central region, an orthogonal projection of the binding region onto the second rigid support layer is located in the fourth central region, and an elastic buffer layer is arranged between the fourth peripheral region and the heat dissipation function layer.

12. The display module according to claim 11, wherein an orthogonal projection of the elastic buffer layer onto the heat dissipation function layer is completely located in the heat dissipation function layer.

13. The display module according to claim 11, wherein a gap is provided between the elastic buffer layer and the second rigid support layer.

14. The display module according to claim 11, wherein the first rigid support layer comprises a graphite layer made of a graphite material.

15. The display module according to claim 9, wherein a driving Integrated Circuit (IC) is arranged at a side of the binding region away from the display region, and in the second direction, a gap between the second rigid support layer and the driving IC is 20 μm to 30 μm.

16. A display device, comprising a display module, and a middle frame arranged outside the display module,
wherein the display module comprises a display panel, wherein the display panel comprises a display region, a bending region and a binding region in a first direction, and the bending region is bent so that the binding region is located at a backlight side of the display region. wherein in a case that the bending region is in a bending state, a heat dissipation function layer is arranged between the display region and the binding region, and a first rigid support layer is arranged between the heat dissipation function layer and the binding region,
wherein the display module further comprises a cover plate arranged at a light-exiting side of the display panel;
a second rigid support layer is arranged at a side of the binding region away from the display region;
the cover plate comprises a first region not covered by the display panel, the first region comprises a first sub-region corresponding to the binding region and a second sub-region other than the first sub-region, and a first adhesive barrier layer is arranged on the second sub-region and coupled to the middle frame;
wherein the display device further comprises a second adhesive barrier layer, the second adhesive barrier layer and the first adhesive barrier layer form an annular structure, and the second adhesive barrier layer covers the second rigid support layer, a portion of the binding region not covered by the second rigid support layer, a portion of the first rigid support layer not covered by the binding region, a portion of the heat dissipation function layer not covered by the first rigid support layer, and a portion of the cover plate.

17. The display device according to claim 16, wherein in a second direction, the first rigid support layer has a first central region and first peripheral regions arranged at two opposite sides of the first central region, and an orthogonal projection of the binding region onto the first rigid support layer is located in the first central region;
in the second direction, the heat dissipation function layer has a second central region and second peripheral regions arranged at two opposite sides of the second central region, and an orthogonal projection of the first rigid support layer onto the heat dissipation function layer is located in the second central region; and
the second direction is perpendicular to the first direction, and the second direction is perpendicular to a light-exiting direction of the display panel.

18. The display device according to claim 16, wherein the heat dissipation function layer is provided with a groove at a side facing the first rigid support layer, and a portion of the first rigid support layer is inserted into the groove.

19. The display device according to claim 18, wherein the heat dissipation function layer comprises a metal layer close to the binding region, and in a light-exiting direction of the display panel, a depth of the groove is smaller than a thickness of the metal layer.

20. The display device according to claim 18, wherein the heat dissipation function layer comprises a metal layer close to the binding region, and a foam layer arranged at a side of the metal layer away from the binding region, wherein in a light-exiting direction of the display panel, a depth of the groove is greater than a thickness of the metal layer, and the depth of the groove is smaller than or equal to a sum of the thickness of the metal layer and a thickness of the foam layer.
